(19) United States
(12) Patent Application Publication
(10) Pub. No.: US 2007/0272474 A1
(43) Pub. Date: Nov. 29, 2007

(54) Low-noise, shock-absorbing, portable speaker cabinet

(76) Inventor: Chi En Huang, Taoyuan City (TW)

Correspondence Address: TROXELL LAW OFFICE, PLLC, SUITE 1404, 5205 LEESBURG PIKE, FALLS CHURCH, VA, 22041, US

(21) Appl. No.: 11/440,464

(22) Filed: May 25, 2006

(51) Int. Cl. H05K 5/00; A47B 81/06

(52) U.S. Cl. 181/148; 181/199

(57) ABSTRACT

Disclosed is a speaker cabinet, which includes a cabinet body, a face panel, which is fixedly provided at the front side of the cabinet body to hold a speaker and has a cross section greater than the cabinet body, and a bracket formed of a curved tube and pivoted with two distal ends thereof to the bottom ends of the two opposite lateral sidewalls of the face panel for use as a support to support the speaker cabinet on the floor or a handle for carrying by hand or a hanger for hanging the speaker cabinet on a tree or the wall.

### BACKGROUND OF THE INVENTION

1. Field of the Invention

The present invention relates speaker cabinets and more specifically, to a low-noise, shock-absorbing, portable speaker cabinet that can be conveniently carried by hand or hung on a tree or the wall.

2. Description of the Related Art

Music is animal activity which involves structured and audible sounds, which is used for artistic or aesthetic, entertainment, or ceremonial purposes. Listening music is the best simple way to release pressure. Following fast development of technology, CD stereo systems have been intensively used in every family to substitute for conventional big-sized transistor radios. Nowadays, people are more critical on sound quality. Except the factor of the quality of the speaker, the quality of the cabinet is also an important factor that determines the sound quality of the speaker system.

Speaker cabinets vary in price. A pair of simple speaker cabinets may value only few ten US dollars. However, a high quality speaker cabinet may cost more than one thousand US dollars. The quality of a speaker cabinet has a great concern with the measure of eliminating resonant noises during output of sound. A high quality speaker cabinet has means to eliminate shocks and to absorb/isolate sounds, thereby achieving perfect reproduction of original sound.

Speaker cabinet manufacturers are trying hard to keep creating new quality products. Taiwan Patent Publication No. M263706 discloses a shock-absorbing foot member for speaker cabinet. According to this design, the shock-absorbing foot member comprises a stem and footpad. The stem has a threaded body and a conical tip at one end of the threaded body. The threaded body is mounted with a block, a cushion, and nuts. The footpad has a top center hole for receiving the conical tip of the stem. Further, the conical tip of the stem is mounted with a shock-absorbing cap. The shock-absorbing cap has a center through hole fort the passing of the threaded body of the stem. The top center hole of the footpad fits the contour of the shock-absorbing cap so that the shock-absorbing cap with the stem can be tightly secured to the footpad. During operation of the speaker, the shock-absorbing cap absorbs shocks. This design of foot member allows the user to shift the position of the speaker cabinet.

Further, FIG. 1 illustrates a speaker cabinet constructed according to the prior art. According to this design, elastic footpads are directly adhered and fastened to the bottom wall of the speaker cabinet at different locations. When the speaker cabinet is placed on the floor, the footpads support the speaker cabinet above the floor. These footpads can absorb shocks in vertical direction. However, they cannot eliminate resonant vibration during sound output performance of the speaker. Because this design of speaker cabinet cannot eliminate resonant vibration, the speaker cannot achieve the best performance.

Further, the shock absorbing design of the aforesaid prior art structure speaker cabinet is fixed monotonous design that is not adjustable. In application, the aforesaid prior art design can only be placed on a table or the floor. It cannot be freely carried by hand or hung on the wall. This limitation narrows the application of the speaker cabinet.

Therefore, it is desirable to provide a speaker cabinet that eliminates the aforesaid drawbacks.

### SUMMARY OF THE INVENTION

The present invention has been accomplished under the circumstances in view. It is the main object of the present invention to provide a low-noise, shock-absorbing, portable speaker cabinet that can be conveniently carried by hand or hung on a tree or the wall. To achieve this and other objects of the present invention, the speaker cabinet comprises a cabinet body, a face panel, and a bracket. The face panel is fixedly provided at the front side of the cabinet body to hold a speaker, having a cross section greater than the cabinet body. The bracket is formed of a curved tube and pivoted with two distal ends thereof to the bottom ends of the two opposite lateral sidewalls of the face panel. Therefore, the bracket can be used as a support to support the speaker cabinet on the floor, a handle for carrying by hand, or a hanger for hanging the speaker cabinet on a tree or the wall.

### BRIEF DESCRIPTION OF THE DRAWINGS

FIG. 1 is a plain view showing the structure of a speaker cabinet according to the prior art.

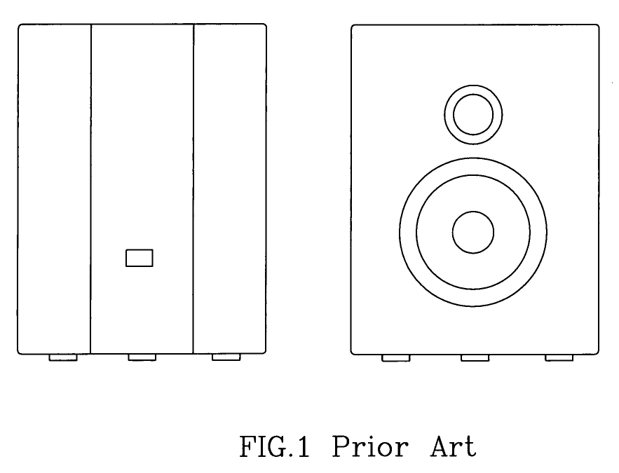

FIG. 2 is an elevational view of a speaker cabinet according to one embodiment of the present invention.

FIG. 3 is a schematic drawing of the present invention, showing the bracket turned relative to the face panel of the speaker cabinet.

FIG. 4 is an applied view of the present invention, showing the user carried the bracket of the speaker cabinet with the hand.

FIG. 5 is another applied view of the present invention, showing the speaker cabinet hung on a tree.

FIG. 6 is a front view of an alternate form of the speaker cabinet according to the present invention, showing an arched design of the bracket.

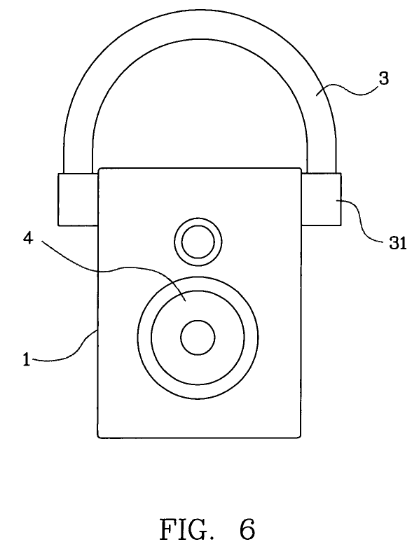

FIG. 7 is a front view of another alternate form of the speaker cabinet according to the present invention, showing a triangular design of the bracket.

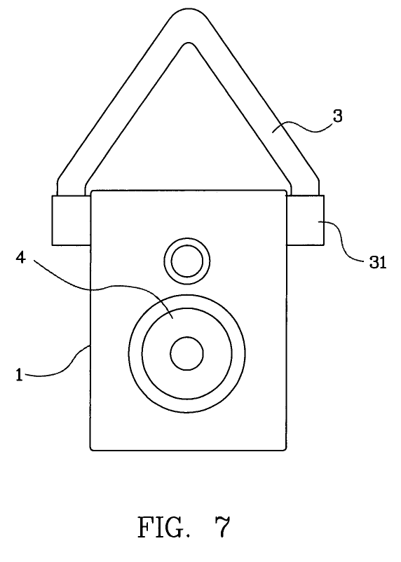

### DETAILED DESCRIPTION OF THE INVENTION

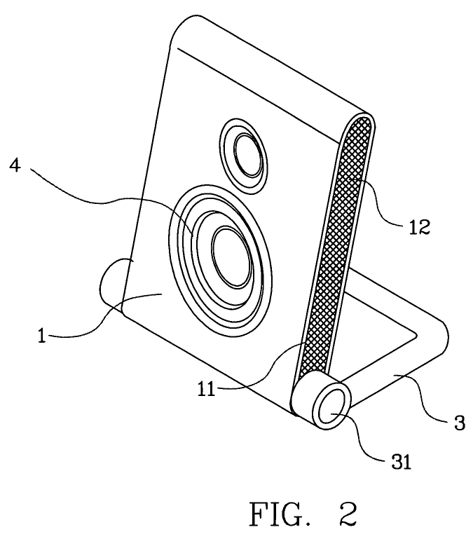

Referring to FIGS. 2˜7, a low-noise, shock-absorbing, portable speaker cabinet in accordance with the present invention is shown comprised of a face panel 1, a cabinet body 2, and a bracket 3. The face panel 1 is provided at the front side of the cabinet body 2, having at least one speaker hole and at least one speaker 4 respectively mounted in the at least one speaker hole. The cabinet body 2 is fixedly connected to the back side of the face panel 1, having a cross section smaller than the face panel 1. The bracket 3 is a curved tubular member pivoted with two distal ends thereof to the bottom ends of the two opposite lateral sides of the face panel 1.

The face panel 1 has two recessed holes 11 respectively disposed at the two opposite lateral sidewalls, and two ornamental strips 12 respectively fitted into the recessed holes 11 to enhance the sense of beauty of the speaker cabinet. The bracket 3 can be made having an arched, corrugated, curved or triangular shape. Further, the bracket 3 has two arms respectively extending from two distal ends of a middle part thereof and terminating in a respective coupling member 31 respectively pivoted to the bottom ends of the two opposite lateral sidewalls of the face panel 1.

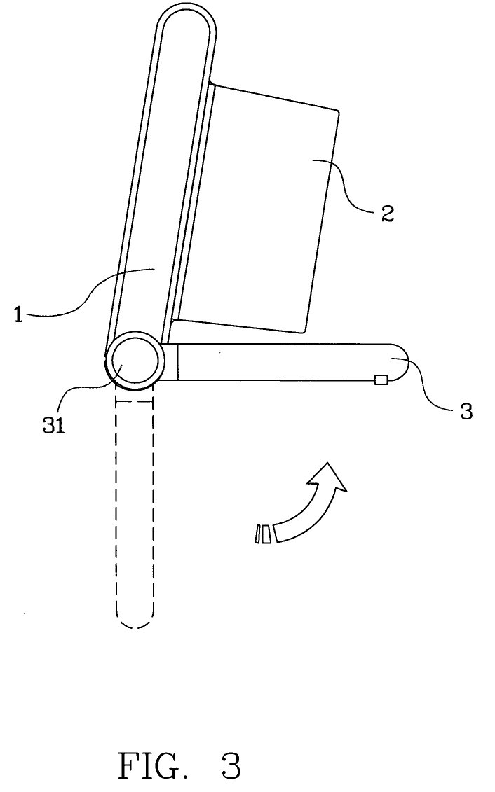

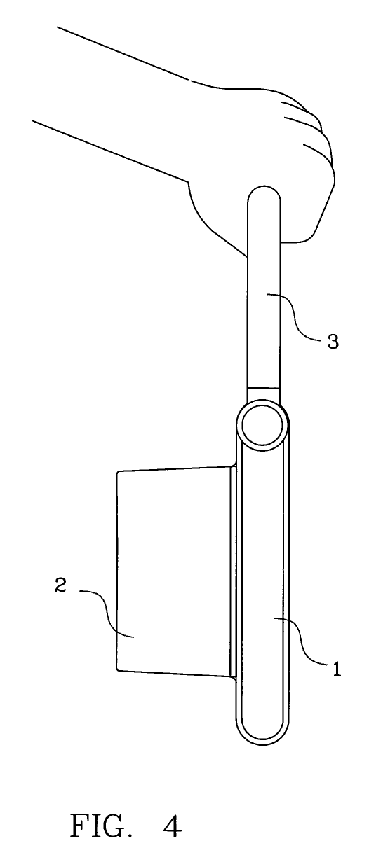

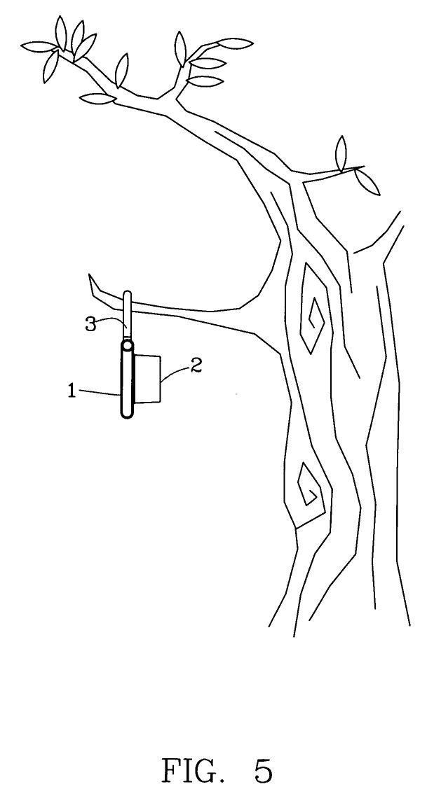

Referring to FIGS. 2 and 3 again, because the bracket 3 is pivoted to the face panel 1, it can be turned relative to the face panel 1 between a horizontal position as shown in FIGS. 2 and 3 and a vertical position as shown in FIGS. 4 and 5. When the bracket 3 is turned to the horizontal position as shown in FIGS. 2 and 3, the bracket 3 can support the speaker cabinet stably on the floor. Because the contact area between the speaker cabinet (the bracket 3) and the floor is a linear contact when the bracket 3 supports the speaker cabinet on the floor, the linear contact between the speaker cabinet and the floor results in excellent shock-absorbing and low-noise effects. Therefore, the design of the present invention effectively improves the output quality of the speaker(s) 4, eliminating the self-shocking drawback of the prior art multiple contact points design during output of sound.

Further, as shown in FIGS. 4 and 5, when the bracket 3 is turned to the top side of the speaker cabinet, i.e., to the vertical position, the bracket 3 can be used as a handle for carrying by hand (see FIG. 4) or as a hanger for hanging on a tree (see FIG. 5) or the wall.

Referring to FIGS. 2˜7 again, the face panel 1 can be made in circular, square or rectangular shape illustrated in the drawings. Alternatively, the face panel 1 can be shaped like a star or flower. The cabinet body 2 can be made in the shape of a cylinder, cube, quadratic prism, or triangular prism. Alternatively, the cabinet body 2 can be shaped like a star or flower.

A prototype of speaker cabinet has been constructed with the features of FIGS. 2˜7. The speaker cabinet functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A low-noise, shock-absorbing, portable speaker cabinet comprising:
a cabinet body;
a face panel fixedly provided at a front side of said cabinet body for holding at least one speaker, said face panel having a cross section greater than said cabinet body; and
a bracket formed of a curved tube, said bracket having two distal ends respectively pivoted to a bottom end of each of two opposite lateral sidewalls of said face panel for enabling said bracket to be selectively used as support means to support the speaker cabinet in a flat surface a handle for carrying by hand or hanging on a high place.

2. The low-noise, shock-absorbing, portable speaker cabinet as claimed in claim 1, wherein said face panel is made in one of circular, square, rectangular, triangular, polygonal, star-like, flower-like shapes.

3. The low-noise, shock-absorbing, portable speaker cabinet as claimed in claim 1, wherein said cabinet body is made in one of the shapes of a cylinder, cube, quadratic prism, triangular prism, star and flower.

4. The low-noise, shock-absorbing, portable speaker cabinet as claimed in claim 1, wherein said bracket has two arms respectively extending from two distal ends of a middle part thereof and terminating in a respective coupling member respectively pivoted to the bottom ends of the two opposite lateral sidewalls of said face panel.

5. The low-noise, shock-absorbing, portable speaker cabinet as claimed in claim 1, wherein said face panel has two recessed holes at two opposite lateral sides thereof and two ornamental strips respectively fitted into said recessed holes.

6. The low-noise, shock-absorbing, portable speaker cabinet as claimed in claim 1, wherein said bracket is made in one of arched, corrugated, curved and triangular shapes.
